(19) United States
(12) Patent Application Publication
(10) Pub. No.: US 2016/0268550 A1
(43) Pub. Date: Sep. 15, 2016

(54) OPTOELECTRONIC COMPONENT AND METHOD FOR PRODUCING AN OPTOELECTRONIC COMPONENT

(71) Applicant: OSRAM OLED GMBH, Regensburg (DE)

(72) Inventors: Daniel Riedel, Regensburg (DE); Thomas Wehlus, Lappersdorf (DE)

(73) Assignee: Osram OLED GmbH, Regensburg (DE)

(21) Appl. No.: 15/030,901

(22) PCT Filed: Oct. 22, 2014
(86) PCT No.: PCT/EP2014/072673

§ 371 Date: Apr. 21, 2016

(30) Foreign Application Priority Data
Oct. 24, 2013 (DE) 10 2013 111 739.2

(51) Int. Cl. H01L 51/52; H01L 51/00; H01L 51/44; H01L 51/56

(52) U.S. Cl. CPC H01L 51/5271; H01L 51/5206; H01L 51/5275; H01L 51/56; H01L 51/0021; H01L 51/5221; H01L 51/442; H01L 2251/301

(57) ABSTRACT

In various embodiments, an optoelectronic component is provided. The optoelectronic component may include a light-transmissive carrier, a light-transmissive electrode above the carrier, an organic functional layer structure, which has a first refractive index, above the first electrode, a light-transmissive current distributing layer above the organic functional layer structure, a light-transmissive TIR layer, which has a second refractive index, which is less than the first refractive index, above the current distributing layer, a specularly reflective current supply layer above the TIR layer, and at least one current conducting element which extends through the TIR layer and electrically couples the current supply layer and the current distributing layer to one another.

### RELATED APPLICATIONS

The present application is a national stage entry according to 35 U.S.C. §371 of PCT application No.: PCT/EP2014/072673 filed on Oct. 22, 2014, which claims priority from German application No.: 10 2013 111 739.2 filed on Oct. 24, 2013, and is incorporated herein by reference in its entirety.

### TECHNICAL FIELD

Various embodiments relate to an optoelectronic component and to a method for producing an optoelectronic component.

### BACKGROUND

Optoelectronic components on an organic basis, for example organic solar cells or organic light emitting diodes (OLEDs), are being used increasingly widely. In particular, OLEDs are being used increasingly in general lighting for example as a surface light source.

Such an optoelectronic component may include an anode and a cathode with an organic functional layer structure therebetween. The organic functional layer structure may include one or a plurality of emitter layers in which electromagnetic radiation is generated, one or a plurality of charge generating layer structures each composed of two or more charge generating layers (CGL) for charge generation, and one or a plurality of electron blocking layers, also designated as hole transport layers (HTL), and one or a plurality of hole blocking layers, also designated as electron transport layers (ETL), in order to direct the current flow.

In the case of a bottom emitter OLED, that is to say an OLED that emits through the substrate or the carrier, the cathode has a double function. It is important for the electrical function of the OLED and it serves as a mirror for light which is generated in the organic functional layer structure and is intended not to leave the OLED on the cathode side. In this case, the efficiency of an OLED with internal coupling-out is influenced very greatly by the reflectivity of the cathode, inter alia. Silver has one of the highest known reflectivities, for example 94% at 550 nm, and is therefore regularly used as cathode material. A silver cathode can exhibit an angle- and wavelength-dependent reflectivity of on average approximately 92%. The material of the cathode, for example the silver, can be vapor-deposited onto the organic functional layer structure, for example.

### SUMMARY

In various embodiments, an optoelectronic component is provided which has a particularly high efficiency.

In various embodiments, a method for producing an optoelectronic component is provided which can be carried out simply and/or cost-effectively and/or which contributes to the optoelectronic component having a particularly high efficiency.

In various embodiments, an optoelectronic component is provided. The optoelectronic component includes a light-transmissive carrier, a light-transmissive electrode above the carrier, and an organic functional layer structure, which has a first refractive index, above the first electrode. A light-transmissive current distributing layer is formed above the organic functional layer structure. A light-transmissive TIR (total internal reflection) layer, which has a second refractive index, which is less than the first refractive index, is formed above the current distributing layer. A specularly reflective current supply layer is formed above the TIR layer. At least one current conducting element extends through the TIR layer and electrically couples the current supply layer to the current distributing layer.

In various embodiments, an optoelectronic component is provided. The optoelectronic component includes a carrier. A specularly reflective current supply layer is formed above the carrier. A light-transmissive TIR layer is formed above the current supply layer. A light-transmissive current distributing layer is formed above the TIR layer. At least one current conducting element extends through the TIR layer and electrically couples the current supply layer to the current distributing layer. An organic functional layer structure, which has a first refractive index, is formed above the current distributing layer. A light-transmissive electrode is formed above the organic functional layer structure. The light-transmissive TIR layer has a second refractive index, which is less than the first refractive index.

“TIR” in German denotes total internal reflection and the “TIR layer” denotes a layer formed to the effect that a particularly high proportion of total internal reflection occurs at the TIR layer during the operation of the optoelectronic component. The electrode above the carrier and below the organic functional layer structure can also be designated as first electrode. The electrode above the organic functional layer structure can also be designated as second electrode. The current distributing layer, the TIR layer, the current conducting elements and the current supply layer form the first or the second electrode, in particular a first electrode structure or a second electrode structure. The TIR layer has a particularly low refractive index and can be designated for example as low index layer. The jump in refractive index from the organic functional layer structure toward the TIR layer provides for a particularly high proportion of total internal reflection at the interface of the TIR layer. In particular, the total internal reflection occurs at the interface of the TIR layer if the incident light is incident on the interface at an angle above the angle of total internal reflection. The light which is not subjected to total internal reflection is reflected at the specularly reflective current supply layer situated behind the TIR layer in the light path direction. Consequently, the light which propagates through the OLED is reflected at the interface with the TIR layer or at the specularly reflective current supply layer, depending on the angle of incidence. The reflection at the TIR layer is virtually free of losses. The reflection at the current supply layer can be the reflectivity of a conventional cathode. A superposition of the reflection characteristics and overall an increased reflection therefore occur. By way of example, the effective reflectivity of a conventional silver cathode can be surpassed. By way of example, the electrode structure including a current supply layer formed by silver and including the TIR layer can exhibit an average reflectivity of approximately 96%. The electrode structure including the TIR layer and the specularly reflective current supply layer therefore has a particularly high reflectivity. This brings about a particularly high efficiency of the optoelectronic component since the power of the OLED is increased primarily in combination with internal coupling-out.

The electrical function of the OLED and in particular of the electrode structure is ensured by the current distributing layer, the current conducting elements and the current supply layer. The current distributing layer can be made very thin, for example. By way of example, the current distributing layer can be made so thin that it makes no or only a negligible contribution to the index jump and only the transition from the organic functional layer structure to the TIR layer is essential for the reflection, in particular the total internal reflection. The current distributing layer can be formed as highly transparent. The current supply layer is the main current carrying unit and the current distributing layer performs the local distribution of the current above and/or below the organic functional layer structure.

The fact that a layer or layer structure is light-transmissive can mean, for example, that the corresponding layer or layer structure is transparent or translucent. The fact that a layer or layer structure is light-transmissive can mean, for example, that the corresponding layer or layer structure is light-transmissive to the light generated by the OLED or, in the case of an organic solar cell, to the light supplied to the solar cell. The fact that the current supply layer is formed as specularly reflective can mean, for example, that the current supply layer is formed as specularly reflective at least at the interface toward the TIR layer.

In addition to the at least one current conducting element, one, two or more further current conducting elements can be arranged which electrically couple the current supply layer to the current distributing layer. The current conducting elements can extend through the TIR layer and/or wholly or partly through the current distributing layer. The current conducting elements can be formed for example in an insular fashion in the TIR layer.

The TIR layer and the current distributing layer can have a well-defined interface with respect to one another. The TIR layer and/or the current distributing layer can in each case be inherently largely homogeneous. As an alternative thereto, the TIR layer and the current distributing layer can little by little and/or gradually merge into one another and/or have a transition gradient. In other words, the material of the TIR layer and of the current distributing layer can be mixed together, wherein toward the organic functional layer structure the proportion of the material of the TIR layer decreases and the proportion of the material of the current distributing layer increases.

In various embodiments, the second refractive index is in a range of 1 to 1.48, for example of 1 to 1.4, for example of 1 to 1.3.

In various embodiments, the TIR layer includes plastic. By way of example, the TIR layer includes synthetic resin.

In various embodiments, the TIR layer includes a foamed material. The material can be foamed by means of air or nitrogen, for example.

In various embodiments, the TIR layer includes epoxy. By way of example, the TIR layer includes epoxy resin.

In various embodiments, the TIR layer includes nanostructures. The nanostructures are nanodots, nanotubes or nanowires, for example. The nanostructures include SiO₂ or carbon, for example. Nanotubes have cavities that make up a particularly large proportion of the volume of the corresponding structure. The cavities can be filled with air and/or nitrogen and then have a refractive index equal to or approximately equal to 1.

In various embodiments, the TIR layer is formed by a cavity. In other words, the TIR layer can be an air layer, a gas layer, a gas cushion or an air cushion.

In various embodiments, the current conducting element is formed as a spacer between the current distributing layer and the current supply layer. This can contribute to being able to form the TIR layer as a cavity in a simple manner.

In various embodiments, the electrode includes nanowires. The nanowires can be silver nanowires, for example. The nanowires can be applied above the carrier in a suspension, for example. In the completed optoelectronic component, residues of the suspension can then still be present or the suspension can be removed apart from the nanowires.

In various embodiments, the current supply layer includes silver. This can contribute to the corresponding electrode structure having a particularly high reflectivity. By way of example, the current supply layer can be formed from silver. By way of example, the current supply layer can be formed in accordance with a conventional silver cathode.

In various embodiments, the current conducting element is formed by electrically conductive adhesion medium. The adhesion medium can for example be adhesive and/or include silver; for example, the adhesion medium can be electrically conductive silver adhesive.

In various embodiments, a method for producing an optoelectronic component is provided, for example the optoelectronic component explained above. In the method, firstly the light-transmissive carrier is provided, for example formed. The light-transmissive electrode is formed above the carrier. The organic functional layer structure, which has the first refractive index, is formed above the first electrode. The light-transmissive current distributing layer is formed above the organic functional layer structure. The light-transmissive TIR layer, which has a second refractive index, which is less than the first refractive index, is formed above the current distributing layer. At least the one current conducting element is formed such that it extends through the TIR layer, wherein the current conducting element serves for electrically coupling the current distributing layer to the specularly reflective current supply layer. The specularly reflective current supply layer is formed above the TIR layer.

In various embodiments, a method for producing an optoelectronic component is provided, for example the optoelectronic component explained above. In the method, the light-transmissive carrier is provided. The light-transmissive electrode is formed above the carrier. The organic functional layer structure, which has the first refractive index, is formed above the first electrode. A cover is provided. The specularly reflective current supply layer is formed above the cover. The light-transmissive TIR layer, which has a second refractive index, which is less than the first refractive index, is formed above the current supply layer. The at least one current conducting element is formed such that it extends through the TIR layer, wherein the current conducting element is formed such that it electrically couples the current distributing layer to the specularly reflective current supply layer. The light-transmissive current distributing layer is formed above the organic functional layer structure or above the TIR layer. The cover with the TIR layer, the current conducting elements and, if appropriate, the current supply layer is arranged above the organic functional layer structure, specifically such that the cover faces away from the organic functional layer structure.

In various embodiments, a method for producing an optoelectronic component is provided. In the method, the carrier is provided. A specularly reflective current supply layer is formed above the carrier. A light-transmissive TIR layer is formed above the specularly reflective current supply layer. At least one current conducting element is formed such that it extends through the TIR layer for the purpose of electrically coupling the specularly reflective current supply layer to the light-transmissive current distributing layer. The light-transmissive current distributing layer is formed above the TIR layer. The organic functional layer structure, which has the first refractive index, is formed above the current distributing layer. A light-transmissive electrode is formed above the organic functional layer structure. The TIR layer has the second refractive index, which is less than the first refractive index.

In various embodiments, a method for producing an optoelectronic component is provided. In the method, the carrier is provided. The specularly reflective current supply layer is formed above the carrier. The light-transmissive TIR layer is formed above the current supply layer and at least one current conducting element is formed such that it extends through the TIR layer for the purpose of electrically coupling the specularly reflective current supply layer to the current distributing layer. A light-transmissive cover is provided. The light-transmissive electrode is formed above the cover. An organic functional layer structure, which has a first refractive index, is formed above the light-transmissive electrode. The light-transmissive current distributing layer is formed above the organic functional layer structure or above the TIR layer. The cover with the light-transmissive electrode and the organic functional layer structure is arranged above the carrier such that the cover faces away from the TIR layer. The TIR layer has a second refractive index, which is less than the first refractive index.

The optoelectronic component can thus be constructed from two halves. The two halves can be adhesively bonded together for example by means of the material of the TIR layer. In this case, the material of the TIR layer and the material of the current conducting elements can be applied to the current supply layer for example in a structured fashion, for example by means of a printing method. Moreover, the material of the current supply layer, of the current distributing layer, of the TIR layer and of the current conducting elements can be applied by means of one or a plurality of printing methods. Consequently, a vacuum process is no longer necessary for forming the second electrode, for example the cathode. If the first electrode and the organic functional layer structure are also applied by printing or are deposited from solution, then a vacuum process is no longer necessary for the production of the optoelectronic component. The material of the current distributing layer, of the TIR layer, of the current conducting elements and/or of the current supply layer can be applied for example by means of a printing method, such as screen printing, blade coating or inkjet printing, for example.

In various embodiments, the material of the TIR layer is foamed. The foaming can be carried out by means of air or nitrogen, for example.

In various embodiments, the TIR layer is formed by a cavity. In other words, the TIR layer can be formed by the cavity being formed.

### BRIEF DESCRIPTION OF THE DRAWINGS

The invention is explained in greater detail below on the basis of an exemplary embodiment, wherein also as before no distinction will be drawn specifically among the claim categories and the features in the context of the independent claims are intended also to be disclosed in other combinations. In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a sectional illustration of a conventional optoelectronic component;

FIG. 2 shows a layer structure of the conventional optoelectronic component in accordance with FIG. 1;

FIG. 3 shows a layer structure of one embodiment of an optoelectronic component;

FIG. 4 shows a detailed sectional illustration of the layer structure of the optoelectronic component in accordance with FIG. 3;

FIG. 5 shows a simplified illustration of the layer structure in accordance with FIG. 4 with exemplary light paths;

FIG. 6 shows a flow diagram of one embodiment of a method for producing an optoelectronic component;

FIG. 7 shows a flow diagram of one embodiment of a method for producing an optoelectronic component;

FIG. 8 shows a detailed sectional illustration of a layer structure of one embodiment of an optoelectronic component;

FIG. 9 shows a flow diagram of one embodiment of a method for producing an optoelectronic component;

FIG. 10 shows a flow diagram of one embodiment of a method for producing an optoelectronic component.

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

An optoelectronic component can be an electromagnetic radiation emitting component or an electromagnetic radiation absorbing component. An electromagnetic radiation absorbing component can be a solar cell, for example. An electromagnetic radiation emitting component can be formed as an organic electromagnetic radiation emitting diode or as an organic electromagnetic radiation emitting transistor. The radiation can be light in the visible range, UV light and/or infrared light, for example. In this context, the electromagnetic radiation emitting component can be formed for example as a light emitting diode (LED), as an organic light emitting diode (OLED), as a light emitting transistor or as an organic light emitting transistor. In various embodiments, the optoelectronic component can be part of an integrated circuit. Furthermore, a plurality of optoelectronic components can be provided, for example in a manner accommodated in a common housing.

The term “translucent” or “translucent layer” can be understood to mean that a layer is transmissive to light, for example to the light generated by the optoelectronic component, for example in one or a plurality of wavelength ranges, for example to light in a wavelength range of visible light (for example at least in a partial range of the wavelength range of 380 nm to 780 nm). By way of example, in various embodiments, the term “translucent layer” should be understood to mean that substantially the entire quantity of light coupled into a structure (for example a layer) is also coupled out from the structure, wherein part of the light can be scattered in this case.

The term “transparent” or “transparent layer” can be understood mean that a layer is transmissive to light (for example at least in a partial range of the wavelength range of 380 nm to 780 nm), wherein light coupled into a structure (for example a layer) is also coupled out from the structure substantially without scattering or light conversion.

A nanostructure is, for example, a structure having at least one external dimension that is smaller than 1000 nm. By way of example, a nanotube or a nanowire can have a diameter of a few nanometers, but can be made significantly larger otherwise, and have a length of up to a few micrometers or even centimeters, for example.

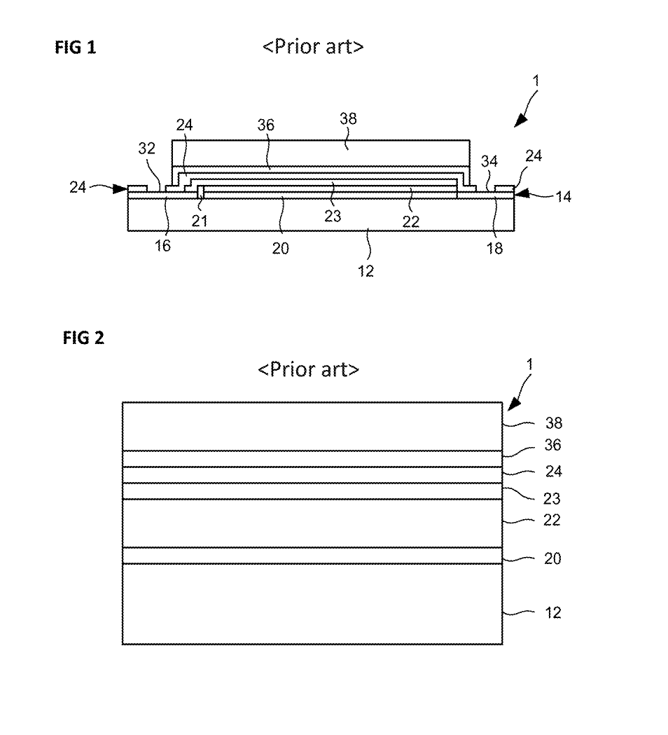

FIG. 1 shows a conventional optoelectronic component 1. The conventional optoelectronic component 1 includes a carrier 12, for example a substrate. An optoelectronic layer structure is formed on the carrier 12.

The optoelectronic layer structure includes a first electrode layer 14 including a first contact section 16, a second contact section 18 and a first electrode 20. The second contact section 18 is electrically coupled to the first electrode 20 of the optoelectronic layer structure. The first electrode 20 is electrically insulated from the first contact section 16 by means of an electrical insulation barrier 21. An organic functional layer structure 22 of the optoelectronic layer structure is formed above the first electrode 20. The organic functional layer structure 22 may include for example one, two or more partial layers, as explained in greater detail further below with reference to FIG. 5. A conventional second electrode 23 of the optoelectronic layer structure is formed above the organic functional layer structure 22, said second electrode being electrically coupled to the first contact section 16. The first electrode 20 serves for example as an anode or cathode of the optoelectronic layer structure. In a manner corresponding to the first electrode 20, the conventional second electrode 23 serves as a cathode or anode of the optoelectronic layer structure.

An encapsulation layer 24 of the optoelectronic layer structure is formed above the conventional second electrode 23 and partly above the first contact section 16 and partly above the second contact section 18, said encapsulation layer encapsulating the optoelectronic layer structure. In the encapsulation layer 24, a first cutout of the encapsulation layer 24 is formed above the first contact section 16 and a second cutout of the encapsulation layer 24 is formed above the second contact section 18. A first contact region 32 is exposed in the first cutout of the encapsulation layer 24 and a second contact region 34 is exposed in the second cutout of the encapsulation layer 24. The first contact region 32 serves for electrically contacting the first contact section 16 and the second contact region 34 serves for electrically contacting the second contact section 18.

An adhesion medium layer 36 is formed above the encapsulation layer 24. The adhesion medium layer 36 includes for example an adhesion medium, for example an adhesive, for example a lamination adhesive, a lacquer and/or a resin. A covering body 38 is formed above the adhesion medium layer 36. The adhesion medium layer 36 serves for fixing the covering body 38 to the encapsulation layer 24. The covering body 38 includes glass and/or metal, for example. For example, the covering body 38 can be formed substantially from glass and include a thin metal layer, for example a metal film, and/or a graphite layer, for example a graphite laminate, on the glass body. The covering body 38 serves for protecting the conventional optoelectronic component 1, for example against mechanical force actions from outside. Furthermore, the covering body 38 can serve for spreading and/or dissipating heat generated in the conventional optoelectronic component 1. By way of example, the glass of the covering body 38 can serve as protection against external actions and the metal layer of the covering body 38 can serve for spreading and/or dissipating the heat that arises during the operation of the conventional optoelectronic component 1.

The covering body 38, the adhesion medium layer 36 and/or the encapsulation layer can be referred to as a cover.

The conventional optoelectronic component 1 can be singulated from a component assemblage, for example, by the carrier 12 being scribed and then broken along its outer edges illustrated laterally in FIG. 1, and by the covering body 38 equally being scribed and then broken along its lateral outer edges illustrated in FIG. 1. The encapsulation layer 24 above the contact regions 32, 34 is exposed during this scribing and breaking. Afterward, the first contact region 32 and the second contact region 34 can be exposed in a further method step, for example by means of an ablation process, for example by means of laser ablation, mechanical scratching or an etching method.

FIG. 2 shows a detailed sectional illustration of a layer structure of the conventional optoelectronic component 1 in accordance with FIG. 1. The conventional optoelectronic component 1 can be formed as a top emitter and/or bottom emitter. If the conventional optoelectronic component 1 is formed as a top emitter and bottom emitter, the conventional optoelectronic component 1 can be referred to as an optically transparent component, for example a transparent organic light emitting diode. If the conventional optoelectronic component 1 is formed as a bottom emitter, then the carrier 12 and the first electrode 20 are formed as transparent or translucent. If the conventional optoelectronic component 1 is formed as a top emitter, then the cover, that is to say the covering body 38, the second electrode 23 and the encapsulation layer 24 are formed as transparent or translucent.

The conventional optoelectronic component 1 includes the carrier 12 and an active region above the carrier 12. A first barrier layer (not illustrated), for example a first barrier thin-film layer, can be formed between the carrier 12 and the active region. The active region includes the first electrode 20, the organic functional layer structure 22 and the conventional second electrode 23. The encapsulation layer 24 is formed above the active region. The encapsulation layer 24 can be formed as a second barrier layer, for example as a second barrier thin-film layer. The covering body 38 is arranged above the active region and, if appropriate, above the encapsulation layer 24. The covering body 38 can be arranged on the encapsulation layer 24 by means of the adhesion medium layer 36, for example.

The active region is an electrically and/or optically active region. The active region is, for example, that region of the conventional optoelectronic component 1 in which electric current for the operation of the conventional optoelectronic component 1 flows and/or in which electromagnetic radiation is generated by the supply of electrical energy or electrical energy is generated by absorption of electromagnetic radiation.

The organic functional layer structure 22 may include one, two or more functional layer structure units and one, two or more intermediate layers between the layer structure units.

The carrier 12 can be formed as translucent or transparent. The carrier 12 serves as a carrier element for electronic elements or layers, for example light emitting elements. The carrier 12 may include or be formed from, for example, glass, quartz, and/or a semiconductor material or any other suitable material. Furthermore, the carrier 12 may include or be formed from a plastics film or a laminate including one or including a plurality of plastics films. The plastic may include one or a plurality of polyolefins. Furthermore, the plastic may include polyvinyl chloride (PVC), polystyrene (PS), polyester and/or polycarbonate (PC), polyethylene terephthalate (PET), polyethersulfone (PES) and/or polyethylene naphthalate (PEN). The carrier 12 may include or be formed from a metal, for example copper, silver, gold, platinum, iron, for example a metal compound, for example steel. The carrier 12 can be formed as a metal film or metal-coated film. The carrier 12 can be a part of a mirror structure or form the latter. The carrier 12 can have a mechanically rigid region and/or a mechanically flexible region or be formed in this way.

The first electrode 20 can be formed as an anode or as a cathode. The first electrode 20 can be formed as translucent or transparent. The first electrode 20 includes an electrically conductive material, for example metal and/or a transparent conductive oxide (TCO) or a layer stack of a plurality of layers including metals or TCOs. The first electrode 20 may include for example a layer stack of a combination of a layer of a metal on a layer of a TCO, or vice versa. One example is a silver layer applied on an indium tin oxide (ITO) layer (Ag on ITO) or ITO—Ag—ITO multilayers.

By way of example, Ag, Pt, Au, Mg, Al, Ba, In, Ca, Sm or Li, and compounds, combinations or alloys of these materials can be used as metal.

Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs.

The first electrode 20 may include, as an alternative or in addition to the materials mentioned: networks composed of metallic nanowires and nanoparticles, for example composed of Ag, networks composed of carbon nanotubes, graphene particles and graphene layers and/or networks composed of semiconducting nanowires. By way of example, the first electrode 20 may include or be formed from one of the following structures: a network composed of metallic nanowires, for example composed of Ag, which are combined with conductive polymers, a network composed of carbon nanotubes which are combined with conductive polymers, and/or graphene layers and composites. Furthermore, the first electrode may include electrically conductive polymers or transition metal oxides.

The first electrode 20 can have for example a layer thickness in a range of 10 nm to 500 nm, for example of 25 nm to 250 nm, for example of 50 nm to 100 nm.

The first electrode 20 can have a first electrical terminal, to which a first electrical potential can be applied. The first electrical potential can be provided by an energy source (not illustrated), for example by a current source or a voltage source. Alternatively, the first electrical potential can be applied to the carrier 12 and the first electrode 20 can be supplied indirectly via the carrier 12. The first electrical potential can be for example the ground potential or some other predefined reference potential.

The organic functional layer structure 22 may include a hole injection layer, a hole transport layer, an emitter layer, an electron transport layer and/or an electron injection layer. The organic functional layer structure 22 and/or one, two or more of the partial layers mentioned can have a first refractive index in a range of 1.7 to 1.8, for example.

The hole injection layer can be formed on or above the first electrode 20. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB(N,N′-bis(naphthalen-2-yl)-N,N′-bis(phenyl)benzidine); TPD(N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD(N,N′-bis(3-methylphenyl)-N,N′-bis(phenyl)-9,9-dimethylfluorene); DMFL-NPB(N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB(N,N′-bis(naphthalen-1-yl)-N,N′-bis(phenyl)-9,9-diphenylfluorene); spiro-TAD (2,2′,7,7′-tetrakis(N,N-diphenylamino)-9,9′-spirobifluorene); 9,9-bis[4-(N,N-bisbiphenyl-4-ylamino)phenyl]-9H-fluorene; 9,9-bis[4-(N,N-bisnaphthalen-2-ylamino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis(N,N-bis(biphenyl-4-yl)amino]-9,9-spirobifluorene; 2,2′-bis(N,N-diphenylamino)-9,9-spirobifluorene; di[4-(N,N-ditolylamino)phenyl]cyclohexane; 2,2′,7,7′-tetra(N,N-ditolyl)aminospirobifluorene; and/or N,N,N′,N′-tetra-naphthalen-2-ylbenzidine.

The hole injection layer can have a layer thickness in a range of approximately 10 nm to approximately 1000 nm, for example in a range of approximately 30 nm to approximately 300 nm, for example in a range of approximately 50 nm to approximately 200 nm.

The hole transport layer can be formed on or above the hole injection layer. The hole transport layer may include or be formed from one or a plurality of the following materials: NPB (N,N′-bis(naphthalen-1-yl)-N,N′-bis(phenyl)benzidine); beta-NPB (N,N′-bis(naphthalen-2-yl)-N,N′-bis(phenyl)benzidine); TPD (N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD (N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetra-kis(N,N-diphenylamino)-9,9′-spirobifluorene); 9,9-bis[4-(N,N-bisbiphenyl-4-yl-amino)phenyl]-9H-fluorene; 9,9-bis[4-(N,N-bisnaphthalen-2-ylamino)phenyl]-9H-fluorene; 9,9-bis[4-(N,N′-bisnaphthalen-2-yl-N,N′-bisphenylamino)phenyl]-9H-fluorene; N,N′-bis(phen-anthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)-9,9-spiro-bifluorene; di[4-(N,N-ditolylamino)phenyl]cyclohexane; 2,2′,7,7′-tetra(N,N-ditolyl)aminospirobifluorene; and N,N,N′,N′-tetranaphthalen-2-ylbenzidine.

The hole transport layer can have a layer thickness in a range of approximately 5 nm to approximately 50 nm, for example in a range of approximately 10 nm to approximately 30 nm, for example approximately 20 nm.

One or a plurality of emitter layers, for example including fluorescent and/or phosphorescent emitters, can be formed on or above the hole transport layer. The emitter layer may include organic polymers, organic oligomers, organic monomers, organic small, non-polymeric molecules (“small molecules”) or a combination of these materials. The emitter layer may include or be formed from one or a plurality of the following materials: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)3 (tris(2-phenylpyridine)iridium III), red phosphorescent Ru (dtb-bpy)3*2(PF6) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited for example by means of thermal evaporation. Furthermore, polymer emitters can be used which can be deposited for example by means of a wet-chemical method, such as, for example, a spin coating method. The emitter materials can be embedded in a suitable manner in a matrix material, for example a technical ceramic or a polymer, for example an epoxy; or a silicone.

The first emitter layer can have a layer thickness in a range of approximately 5 nm to approximately 50 nm, for example in a range of approximately 10 nm to approximately 30 nm, for example approximately 20 nm.

The emitter layer may include emitter materials that emit in one color or in different colors (for example blue and yellow or blue, green and red). Alternatively, the emitter layer may include a plurality of partial layers which emit light of different colors. By means of mixing the different colors, the emission of light having a white color impression can result. Alternatively or additionally, provision can be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The electron transport layer can be formed, for example deposited, on or above the emitter layer. The electron transport layer may include or be formed from one or a plurality of the following materials: NET-18; 2,2′,2″-(1,3,5-benzinetriyl)tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium; 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron transport layer can have a layer thickness in a range of approximately 5 nm to approximately 50 nm, for example in a range of approximately 10 nm to approximately 30 nm, for example approximately 20 nm.

The electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10- phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1, 10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron injection layer can have a layer thickness in a range of approximately 5 nm to approximately 200 nm, for example in a range of approximately 20 nm to approximately 50 nm, for example approximately 30 nm.

In the case of an organic functional layer structure 22 including two or more organic functional layer structure units, corresponding intermediate layers can be formed between the organic functional layer structure units. The organic functional layer structure units can be formed in each case individually by themselves in accordance with a configuration of the organic functional layer structure 22 explained above. The intermediate layer can be formed as an intermediate electrode. The intermediate electrode can be electrically connected to an external voltage source. The external voltage source can provide a third electrical potential, for example, at the intermediate electrode. However, the intermediate electrode can also have no external electrical terminal, for example by the intermediate electrode having a floating electrical potential.

The organic functional layer structure unit can have for example a layer thickness of a maximum of approximately 3 μm, for example a layer thickness of a maximum of approximately 1 μm, for example a layer thickness of a maximum of approximately 300 nm.

The conventional optoelectronic component 1 can optionally include further functional layers, for example arranged on or above the one or the plurality of emitter layers or on or above the electron transport layer. The further functional layers can be for example internal or external coupling-in/coupling-out structures that can further improve the functionality and thus the efficiency of the conventional optoelectronic component 10.

The conventional second electrode 23 can be formed in accordance with one of the configurations of the first electrode 20, wherein the first electrode 20 and the conventional second electrode 23 can be formed identically or differently. The conventional second electrode 23 can be formed as an anode or as a cathode. The conventional second electrode 23 can have a second electrical terminal, to which a second electrical potential can be applied. The second electrical potential can be provided by the same energy source as, or a different energy source than, the first electrical potential. The second electrical potential can be different than the first electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The encapsulation layer 24 can also be designated as thin-film encapsulation. The encapsulation layer 24 can be formed as a translucent or transparent layer. The encapsulation layer 24 forms a barrier against chemical impurities or atmospheric substances, in particular against water (moisture) and oxygen. In other words, the encapsulation layer 24 is formed in such a way that substances that can damage the optoelectronic component, for example water, oxygen or solvent, cannot penetrate through it or at most very small proportions of said substances can penetrate through it. The encapsulation layer 24 can be formed as an individual layer, a layer stack or a layer structure.

The encapsulation layer 24 may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenyleneterephthalamide), nylon 66, and mixtures and alloys thereof.

The encapsulation layer 24 can have a layer thickness of approximately 0.1 nm (one atomic layer) to approximately 1000 nm, for example a layer thickness of approximately 10 nm to approximately 100 nm, for example approximately 40 nm. The encapsulation layer 24 may include a high refractive index material, for example one or a plurality of material(s) having a high refractive index, for example having a refractive index of 1.5 to 3, for example of 1.7 to 2.5, for example of 1.8 to 2.

If appropriate, the first barrier layer can be formed on the carrier 12 in a manner corresponding to a configuration of the encapsulation layer 24.

The encapsulation layer 24 can be formed for example by means of a suitable deposition method, e.g. by means of an atomic layer deposition (ALD) method, e.g. a plasma enhanced atomic layer deposition (PEALD) method or a plasmaless atomic layer deposition (PLALD) method, or by means of a chemical vapor deposition (CVD) method, e.g. a plasma enhanced chemical vapor deposition (PECVD) method or a plasmaless chemical vapor deposition (PLCVD) method, or alternatively by means of other suitable deposition methods.

If appropriate, a coupling-in or coupling-out layer can be formed for example as an external film (not illustrated) on the carrier 12 or as an internal coupling-out layer (not illustrated) in the layer cross section of the optoelectronic component 10. The coupling-in/-out layer may include a matrix and scattering centers distributed therein, wherein the average refractive index of the coupling-in/-out layer is greater than the average refractive index of the layer from which the electromagnetic radiation is provided. Furthermore, in addition, one or a plurality of antireflection layers can be formed.

The adhesion medium layer 36 may include adhesive and/or lacquer, for example, by means of which the covering body 38 is arranged, for example adhesively bonded, on the encapsulation layer 24, for example. The adhesion medium layer 36 can be formed as transparent or translucent. The adhesion medium layer 36 may include for example particles which scatter electromagnetic radiation, for example light-scattering particles. As a result, the adhesion medium layer 36 can act as a scattering layer and lead to an improvement in the color angle distortion and the coupling-out efficiency.

The light-scattering particles provided can be dielectric scattering particles, for example composed of a metal oxide, for example silicon oxide (SiO₂), zinc oxide (ZnO), zirconium oxide (ZrO₂), indium tin oxide (ITO) or indium zinc oxide (IZO), gallium oxide (Ga₂Oₓ), aluminum oxide, or titanium oxide. Other particles may also be suitable provided that they have a refractive index that is different than the effective refractive index of the matrix of the adhesion medium layer 36, for example air bubbles, acrylate, or hollow glass beads. Furthermore, by way of example, metallic nanoparticles, metals such as gold, silver, iron nanoparticles, or the like can be provided as light-scattering particles.

The adhesion medium layer 36 can have a layer thickness of greater than 1 μm, for example a layer thickness of a plurality of μm. In various embodiments, the adhesive can be a lamination adhesive.

The adhesion medium layer 36 can have a refractive index that is less than the refractive index of the covering body 38. The adhesion medium layer 36 may include for example a low refractive index adhesive such as, for example, an acrylate having a refractive index of approximately 1.3. However, the adhesion medium layer 36 can also include a high refractive index adhesive which for example includes high refractive index, non-scattering particles and has a layer-thickness-averaged refractive index that approximately corresponds to the average refractive index of the organic functional layer structure 22, for example in a range of approximately 1.6 to 2.5, for example of 1.7 to approximately 2.0.

A so-called getter layer or getter structure, i.e. a laterally structured getter layer, can be arranged (not illustrated) on or above the active region. The getter layer can be formed as translucent, transparent or opaque. The getter layer may include or be formed from a material that absorbs and binds substances that are harmful to the active region. A getter layer may include or be formed from a zeolite derivative, for example. The getter layer can have a layer thickness of greater than 1 μm, for example a layer thickness of a plurality of μm. In various embodiments, the getter layer may include a lamination adhesive or be embedded in the adhesion medium layer 36.

The covering body 38 can be formed for example by a glass body, a metal film or a sealed plastics film covering body. The covering body 38 can be arranged on the encapsulation layer 24 or the active region for example by means of frit bonding (glass frit bonding/glass soldering/seal glass bonding) by means of a conventional glass solder in the geometrical edge regions of the optoelectronic component 10. The covering body 38 can have for example a refractive index of for example 1.3 to 3, for example of 1.4 to 2, for example of 1.5 to 1.8.

FIG. 3 shows a sectional illustration of a layer structure of one embodiment of an optoelectronic component 10. The optoelectronic component 10 or the layer structure of the optoelectronic component 10 can largely correspond to the conventional optoelectronic component 1 or the conventional layer structure thereof as explained above.

The optoelectronic component 10 includes a second electrode structure 40 instead of the conventional second electrode 23 as second electrode. With respect to the light generated in the organic functional layer structure 22, the second electrode structure 40 has an increased reflectivity compared with the conventional second electrode 23, as a result of which the coupling-out efficiency and thus the efficiency of the optoelectronic component 10 is increased compared with the conventional optoelectronic component 1.

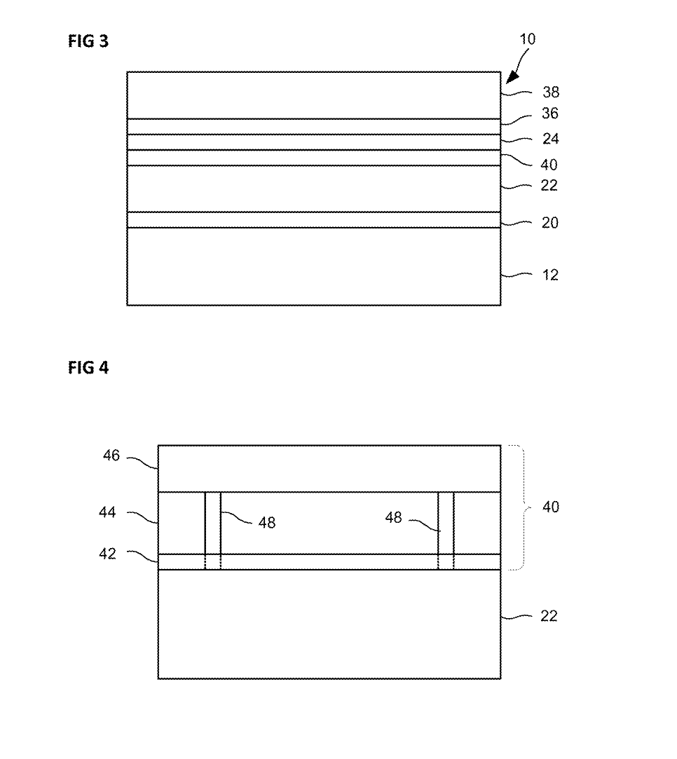

FIG. 4 shows a detailed view of the layer structure in accordance with FIG. 3, in particular of the organic functional layer structure 22 and the second electrode structure 40. The second electrode structure 40 includes a current distributing layer 42, which is formed above the organic functional layer structure 22, for example directly on the organic functional layer structure 22. The second electrode structure 40 furthermore includes a TIR layer 44, which is formed above the current distributing layer 42, for example directly on the current distributing layer 42. Furthermore, the second electrode structure 40 includes a current supply layer 46, which is formed above the TIR layer 44, for example directly on the TIR layer 44. Furthermore, the second electrode structure 40 includes current conducting elements 48, which electrically couple the current supply layer 46 to the current distributing layer 42. The current conducting elements 48 extend for example from the current supply layer 46 through the TIR layer 44 as far as the current distributing layer 42. The current conducting elements 48 can terminate flush with an interface of the current distributing layer 42 facing the TIR layer 44 or can extend partly or wholly through the current distributing layer 42.

The current distributing layer 42 can be made particularly thin compared with the TIR layer 44. By way of example, the current distributing layer 42 can be made so thin that its refractive index for the light generated in the organic functional layer structure 22 in the transition toward the TIR layer 44 is not relevant or is at least negligible. By way of example, the current distributing layer 42 can have a thickness that is significantly smaller than the wavelength of the generated light. The current distributing layer 42 can be formed as transparent or translucent, for example.

The current distributing layer 42 may include or be formed by nanostructures, for example. The nanostructures may include nanowires or nanotubes, for example. The nanostructures may include silver and/or carbon, for example. The nanowires may include silver nanowires, for example. As an alternative thereto, the current distributing layer 42 may include one or a plurality of conductive ALD or CVD layers, that is to say layers formed by means of ALD (atomic layer deposition) or CVD (chemical vapor deposition). Such a layer may include for example a TCO, as explained above, and/or zinc oxide or tin oxide, for example.

The current distributing layer 42 can have a thickness in a range for example of 1 nm to 50 nm, for example of 5 nm to 20 nm. The current distributing layer 42 can have an electrical sheet resistance in a range of for example 50 ohms/sq to 200 ohms/sq, for example approximately 100 ohms/sq.

The current distributing layer 42 serves to distribute, via the interface which it shares with the organic functional layer structure 22, the current supplied to it by the current supply layer 46 via the current conducting elements 48. The current distributing layer 42 can be for example so thin and/or so transparent or translucent that it absorbs a maximum of 1% of the light which is generated by the optoelectronic component 10 and impinges on it.

The TIR layer 44 is formed for example as light-transmissive and/or electrically insulating. The TIR layer 44 has a second refractive index, which is less than the first refractive index of the organic functional layer structure 22. By way of example, the first refractive index is between 1.7 and 1.8 and the second refractive index is less than 1.7. The TIR layer has, in particular, a lower refractive index than the layer of the organic functional layer structure 22 which adjoins the current distributing layer 42. The second refractive index can be for example in a range for example of 1 to 1.48, of 1 to 1.3, for example of 1 to 1.2, for example of 1 to 1.1.

The TIR layer 44 may include for example a plastic, for example a synthetic resin, for example an epoxy, for example epoxy resin. Alternatively or additionally, the TIR layer 44 can be foamed. By way of example, the material of the TIR layer 44 can be foamed with the aid of air or nitrogen, such that a large proportion of the volume of the TIR layer 44 consists of cavities filled with air or nitrogen. Such cavities have the refractive index 1 and contribute to the particularly low refractive index of the entire TIR layer 44. In this context, the material of the TIR layer 44 may include for example epoxy, a polymer and/or acrylate, which are processed in a sol-gel method, for example. Alternatively or additionally, the TIR layer 44 may include nanostructures, for example nanotubes. The nanotubes may include silicon dioxide or carbon. The nanotubes have a particularly high proportion by volume of cavities formed for example within the nanotubes or between the nanotubes, for example between different nanotubes. Said cavities can in turn be filled with air or nitrogen, which contributes to the second refractive index of the TIR layer 44 being 1 or at least almost 1. Furthermore, the TIR layer 44 may include or be formed by a metal fluoride, for example aluminum fluoride having a refractive index of 1.35, or a metal oxide. The TIR layer 44 including metal fluoride or metal oxide can be formed in a sol-gel method, for example. By way of example, a nanoporous material can be formed in the sol-gel method, said nanoporous material having pores whose size is for example less than 100 nm, for example less than 50 nm, for example less than 10 nm, for example an aerogel.

The TIR layer 44 can be formed for example such that structures of the TIR layer 44, for example pores or nanostructures, are smaller than the wavelength of the generated light. This can contribute to preventing or minimizing a scattering of the generated light in the TIR layer 44.

As an alternative thereto, the TIR layer 44 can be formed by a cavity. In other words, the TIR layer 44 can be an air or gas cushion and/or an air or an air buffer, that is to say an air or a gas layer. In this case, the second refractive index is 1, which brings about a high proportion of total internal reflection. In this context, it may be advantageous if the current conducting elements 48 are formed stably enough that they can serve as spacers between the current distributing layer 42 and the current supply layer 46.

The TIR layer 44 serves to provide a particularly large jump in refractive index in the transition from the organic functional layer structure 22 to the TIR layer 44. The particularly large jump in refractive index has the effect that a large proportion of the light generated in the organic functional layer structure 22 is subjected to total internal reflection at the interface toward the TIR layer 44, in particular that proportion of the generated light which impinges on the interface with the TIR layer 44 at an angle of incidence that is greater than the critical angle of total internal reflection. The angle of incidence and the critical angle are determined with respect to a surface normal, that is to say a perpendicular, to the interface with the TIR layer 44. The critical angle of total internal reflection is dependent on the size of the jump in refractive index and decreases as the size of the jump in refractive index increases. That is to say that as the size of the jump in refractive index increases, the critical angle of total internal reflection decreases and an increasing proportion of the light has an angle of incidence that is greater than the critical angle, and a correspondingly increasing proportion of the generated light is subjected to total internal reflection at the interface.

With regard to its construction and/or material, the current supply layer 46 can be formed in accordance with a configuration of the second electrode 23 explained in association with the conventional optoelectronic component 1. By way of example, the current supply layer 46 may include or be formed from silver.

The current conducting elements 48 include an electrically conductive material. By way of example, the current conducting elements 48 can be formed by an electrically conductive adhesion medium, for example by electrically conductive paste, for example by silver conductive adhesive. As an alternative thereto, the current conducting elements 48 can be formed by a hard material, for example by soldering tin or copper. The current conducting elements 48 are embedded into the TIR layer 44 and are enclosed by the material of the TIR layer 44 in a horizontal direction in FIG. 4. As an alternative to the two current conducting elements 48, just one current conducting element 48 or else more than two, for example three, four or more, current conducting elements 48 can be arranged.

FIG. 5 shows a simplified illustration of the layer structure in accordance with FIG. 4, wherein the current conducting elements 48 are not illustrated for reasons of clarity.

FIG. 5 furthermore shows exemplary light paths of the light that is generated in the organic functional layer structure 22. For reasons of enabling better illustration, exclusively light paths that originate at a central point in the organic functional layer structure 22 are illustrated. In actual fact, however, the light is generated within a large areal region in the organic functional layer structure 22 during the operation of the optoelectronic component 10, thus giving rise to a multiplicity of light paths that cannot be illustrated pictorially.

First light paths 50 represent the light which is generated in the organic functional layer structure 22 and is emitted in a direction toward the TIR layer 44 and the current supply layer 46. A first part of the light passing along the first light paths 50, in particular the first part of the light whose angle of incidence is less than the critical angle of total internal reflection at the interface of the TIR layer 44, enters the TIR layer 44, is refracted at said interface and passes further along second light paths 52 toward the current supply layer 46. The light which passes through the TIR layer 44 along the second light paths 52 impinges on the current supply layer 46 and is reflected at the specularly reflective current supply layer 46. If the current supply layer 46 is formed by silver, then for example 92% of the light that passes along the second light paths 52 can be correspondingly reflected. The light reflected at the current supply layer 46 can for example pass along third light paths and back in a direction toward the current distributing layer 42 and the organic functional layer structure 22 and can furthermore be emitted out of the optoelectronic component 10 through the carrier 12.

A second part of the light generated in the organic functional layer structure 22 and passing along the first light paths 50 impinges on the interface of the TIR layer 44 at an angle of incidence that is greater than the critical angle of total internal reflection. Therefore, the second proportion of the light is subjected to total internal reflection at the TIR layer and can be emitted for example along fourth light paths 56 through the organic functional layer structure 22, through the first electrode 20, through the carrier and out of the optoelectronic component 10. The total internal reflection 56 takes place virtually without any losses, such that approximately the entire second proportion of the light is reflected back. Together with the reflection at the current supply layer 46, this results in a total reflectivity of the second electrode structure 40 which is significantly increased compared with the reflectivity of the conventional second electrode 23. By way of example, an average reflectivity of the second electrode structure of 96%, for example, can be obtained. This can contribute to the efficiency of the optoelectronic component 10 being particularly high.

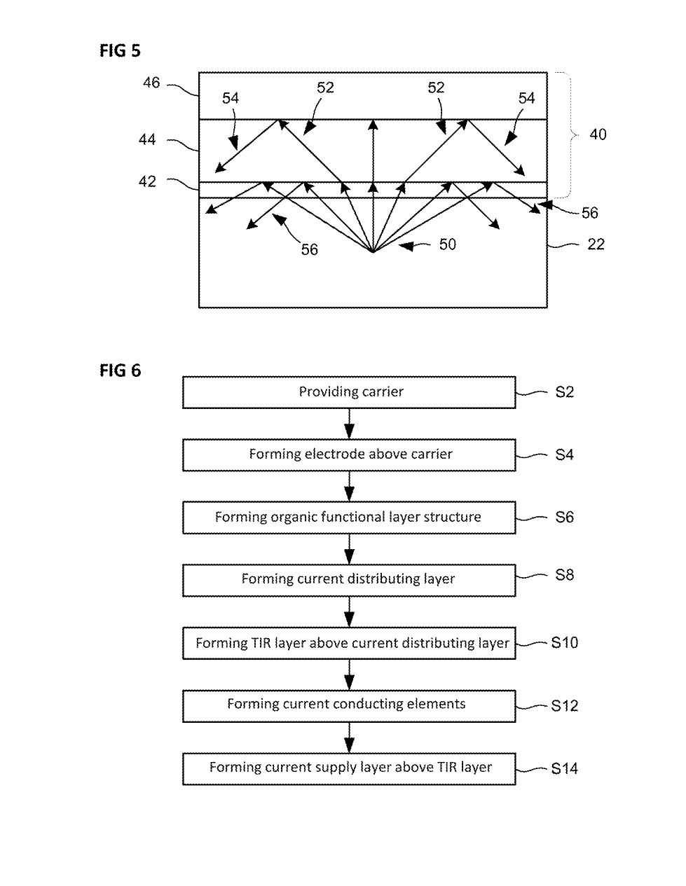

FIG. 6 shows a flow diagram of one embodiment of a method for producing an optoelectronic component, for example the optoelectronic component 10 explained above.

A step S2 involves providing a carrier, for example the carrier 12 explained above. Providing the carrier 12 may include for example forming the carrier 12, for example from a transparent substrate, for example a glass substrate or a film. Furthermore, step S2 can involve, if appropriate, forming one or a plurality of barrier layers, coupling-out layers, for example scattering layers, and/or other intermediate layers on the carrier 12.

A step S4 involves forming an electrode, for example the first electrode 20 explained above, above the carrier 12. The first electrode 20 can for example be deposited above the carrier 12 or be printed onto the latter.

A step S6 involves forming an organic functional layer structure. By way of example, the organic functional layer structure 22 explained above is formed above the first electrode 20. By way of example, the organic functional layer structure 22 can be deposited layer by layer or printed layer by layer.

A step S8 involves forming a current distributing layer. By way of example, the current distributing layer 42 explained above is formed above the organic functional layer structure 22. The current distributing layer 42 can be formed for example by electrically conductive elements, for example the electrically conductive nanostructures, being dissolved in a suspension and the suspension being applied to the organic functional layer structure 22. The carrier liquid of the suspension can then be partly or completely removed, for example by means of drying or evaporation. As an alternative thereto, the carrier liquid used can be a drying or curing material that cures after being applied to the organic functional layer structure 22.

A step S10 involves forming a TIR layer. By way of example, the TIR layer 44 is formed above the current distributing layer 42. The material of the TIR layer 44 can for example be deposited on the current distributing layer 42 or be printed onto the latter. Furthermore, the material of the TIR layer 44 can be foamed, for example by means of air or nitrogen, before being applied or after being applied to the current distributing layer 42. As an alternative thereto, the TIR layer 44 can be formed by creating a cavity, in particular a free volume above the current distributing layer 42.

A step S12 involves forming current conducting elements, for example the current conducting elements explained above. By way of example, holes can be formed in the TIR layer 42 and the material of the current conducting elements 48 can be filled and/or introduced into the TIR layer 44.

The order in which steps S10 and S12 are processed can vary depending on how the current conducting elements 48 are formed. If, for example, alternatively, firstly step S12 and then step S10 are performed, wherein firstly the current conducting elements 48 are formed and then the TIR layer 44 is formed, the current conducting elements 48 can be formed, for example, by soldering points being applied to the current distributing layer 42, by an electrically conductive adhesion medium being applied, for example at points, to the current distributing layer 42, or by solid small electrically conductive elements, for example copper points or cylinders, being applied to the current distributing layer 42. Afterward, the TIR layer 44 can be formed, specifically around the current conducting elements 48. If the TIR layer 44 is formed by a cavity or a free volume, for example firstly the current conducting elements 48 can be formed as spacers and then the current supply layer 46 can be applied to the current conducting elements 48 in such a way that the cavity remains between the current supply layer 46 and the current distributing layer 42. As an alternative thereto, the TIR layer 44 and the current conducting elements 48 can be formed simultaneously. By way of example, the TIR layer 44 and the current conducting elements 48 can be formed in one work step, for example by means of a printing method.

A step S14 involves forming a current supply layer above the TIR layer 44, for example the current supply layer 46. The current supply layer 46 can be formed for example in accordance with a configuration of the conventional second electrode 23.

Optionally, for example, the encapsulation layer 24, the adhesion medium layer 36 and/or the covering body 38 can also be arranged and/or formed above the current supply layer 46.

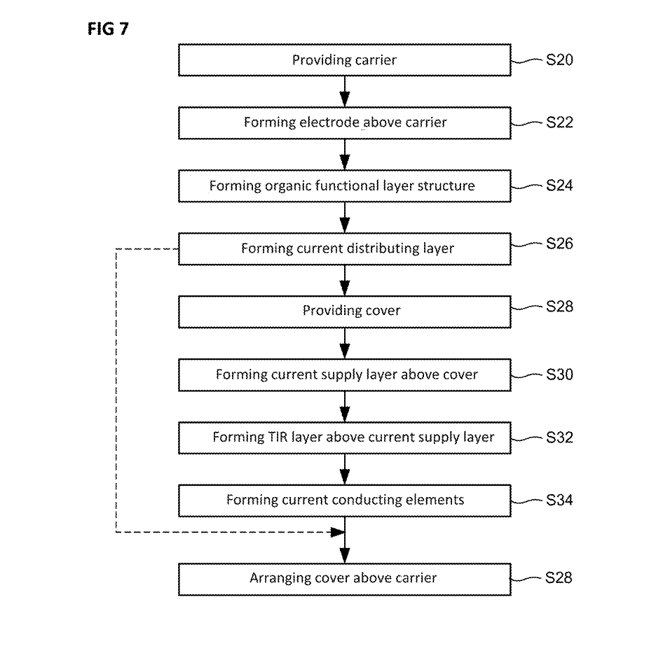

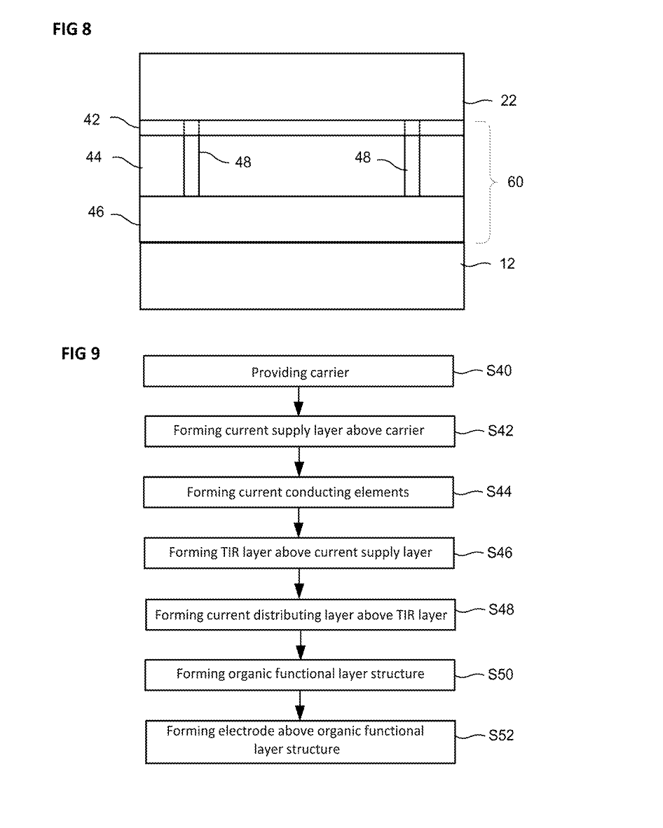

FIG. 7 shows a flow diagram of one embodiment of an alternative method for producing an optoelectronic component, for example the component 10 explained above.

Steps S20 to S26 can be processed for example analogously to steps S2 to S8 of the method explained above.

A step S26 involves forming a current distributing layer, for example the current distributing layer 42 explained above. The current distributing layer 42 can be formed for example in accordance with step S8, specifically above the organic functional layer structure 22.

As an alternative thereto, step S26 can also be implemented after a step S34. In particular, the current distributing layer 42 can also be formed above the TIR layer 44, which, as explained below, is formed above a cover.

A step S28 can involve providing the cover. By way of example, the cover may include the covering body 38, the adhesion medium layer 36 and/or the encapsulation layer 44.

A step S30 involves forming a current supply layer, for example the current supply layer 46 explained above, above the cover, for example directly on the cover. By way of example, the current supply layer 46 can be deposited on the cover. The current supply layer 46 can be formed for example in accordance with a configuration of the conventional second conventional electrode 23.

A step S32 involves forming the TIR layer 44 above the current supply layer 46. Forming the TIR layer 44 in step S32 can be carried out substantially analogously to forming the TIR layer 44 above the current distributing layer 42 in step S10.

A step S34 involves forming current conducting elements, for example the current conducting elements 48. The current conducting elements 48 are formed in the TIR layer 44.

Forming the TIR layer 44 and the current conducting elements 48 can be carried out for example analogously to forming the current conducting elements 48 and the TIR layer 44 in accordance with steps S10 and S12. In particular, the order of the processing of steps S10 and S12 can be dependent on the type of the current conducting elements 48 and/or the TIR layer 44.

Optionally, step S26 can then be carried out and the current distributing layer 42 can be formed above the TIR layer 44.

In a step S28, the cover with the current supply layer 46, the TIR layer 44 and the current conducting elements 48 is arranged above the carrier 12 such that the current conducting elements 48, the current supply layer 46 and the current distributing layer 42 are electrically coupled to one another. In particular, the cover is arranged such that the covering body 38 faces away from the organic functional layer structure 22.

FIG. 8 shows a detailed view of a layer structure of one embodiment of an optoelectronic component 10. As considered by themselves, the individual layers can be formed for example in accordance with one of the configurations of the corresponding layers as explained above, but the layers can be arranged in a different sequence.

In particular, the layer structure includes a first electrode structure 60 as an alternative or in addition to the first electrode 20. The first electrode structure 40 includes the current distributing layer 42, wherein the current distributing layer 42 is formed below the organic functional layer structure 22, for example directly below the organic functional layer structure 22. The first electrode structure 60 furthermore includes the TIR layer 44, wherein the TIR layer 44 is formed below the current distributing layer 42, for example directly below the current distributing layer 42. Furthermore, the first electrode structure 60 includes the current supply layer 46, wherein the current supply layer 46 is formed below the TIR layer 44, for example directly below the TIR layer 44. Furthermore, the first electrode structure 60 includes the current conducting elements 48, which electrically couple the current supply layer 46 to the current distributing layer 42. The current conducting elements 48 extend for example from the current supply layer 46 through the TIR layer 44 as far as the current distributing layer 42. The current conducting elements 48 can terminate flush with an interface of the current distributing layer 42 facing the TIR layer 44 or can extend partly or wholly through the current distributing layer 42.

The current distributing layer 42 can be made particularly thin compared with the TIR layer 44. By way of example, the current distributing layer 42 can be made so thin that its refractive index for the light generated in the organic functional layer structure 22 in the transition toward the TIR layer 44 is not relevant or is at least negligible. By way of example, the current distributing layer 42 can have a thickness that is significantly smaller than the wavelength of the generated light. The current distributing layer 42 can be formed as transparent or translucent, for example.

The current distributing layer 42 may include or be formed by nanostructures, for example. The nanostructures may include nanowires or nanotubes, for example. The nanostructures may include silver and/or carbon, for example. The nanowires may include silver nanowires, for example. As an alternative thereto, the current distributing layer 42 may include one or a plurality of conductive ALD or CVD layers, that is to say layers formed by means of ALD (atomic layer deposition) or CVD (chemical vapor deposition). Such a layer may include for example a TCO, as explained above, and/or zinc oxide or tin oxide, for example.

The current distributing layer 42 can have a thickness in a range for example of 1 nm to 50 nm, for example of 5 nm to 20 nm. The current distributing layer 42 can have an electrical sheet resistance in a range of for example 20 ohms/sq to 200 ohms/sq, for example approximately 100 ohms/sq.

The current distributing layer 42 serves to distribute, via the interface which it shares with the organic functional layer structure 22, the current supplied to it by the current supply layer 46 via the current conducting elements 48. The current distributing layer 42 can be for example so thin and/or so transparent or translucent that it absorbs a maximum of 1% of the light which is generated by the optoelectronic component 10 and impinges on it.

The TIR layer 44 is formed for example as light-transmissive and/or electrically insulating. The TIR layer 44 has a second refractive index, which is less than the first refractive index of the organic functional layer structure 22. By way of example, the first refractive index is between 1.7 and 1.8 and the second refractive index is less than 1.7. The TIR layer has, in particular, a lower refractive index than the layer of the organic functional layer structure 22 which adjoins the current distributing layer 42. The second refractive index can be for example in a range for example of 1 to 1.48, for example of 1 to 1.3, for example of 1 to 1.2, for example of 1 to 1.1.

The TIR layer 44 may include for example a plastic, for example a synthetic resin, for example an epoxy, for example epoxy resin. Alternatively or additionally, the TIR layer 44 can be foamed. By way of example, the material of the TIR layer 44 can be foamed with the aid of air or nitrogen, such that a large proportion of the volume of the TIR layer 44 consists of cavities filled with air or nitrogen. Such cavities have the refractive index 1 and contribute to the particularly low refractive index of the entire TIR layer 44. In this context, the material of the TIR layer 44 may include for example epoxy, a polymer and/or acrylate, which are processed in a sol-gel method, for example. Alternatively or additionally, the TIR layer 44 may include nanostructures, for example nanotubes. The nanotubes may include silicon dioxide or carbon. The nanotubes have a particularly high proportion by volume of cavities formed for example within the nanotubes or between the nanotubes, for example between different nanotubes. Said cavities can in turn be filled with air or nitrogen, which contributes to the second refractive index of the TIR layer 44 being 1 or at least almost 1. Furthermore, the TIR layer 44 may include or be formed by a metal fluoride, for example aluminum fluoride having a refractive index of 1.35, or a metal oxide. The TIR layer 44 including metal fluoride or metal oxide can be formed in a sol-gel method, for example. By way of example, a nanoporous material can be formed in the sol-gel method, said nanoporous material having pores whose size is for example less than 100 nm, for example less than 50 nm, for example less than 10 nm, for example an aerogel.

The TIR layer 44 can be formed for example such that structures of the TIR layer 44, for example pores or nanostructures, are smaller than the wavelength of the generated light. This can contribute to preventing or minimizing a scattering of the generated light in the TIR layer 44.

As an alternative thereto, the TIR layer 44 can be formed by a cavity. In other words, the TIR layer 44 can be an air or gas cushion and/or an air or an air buffer, that is to say an air or a gas layer. In this case, the second refractive index is 1, which brings about a high proportion of total internal reflection. In this context, it may be advantageous if the current conducting elements 48 are formed stably enough that they can serve as spacers between the current distributing layer 42 and the current supply layer 46.

The TIR layer 44 serves to provide a particularly large jump in refractive index in the transition from the organic functional layer structure 22 to the TIR layer 44. The particularly large jump in refractive index has the effect that a large proportion of the light generated in the organic functional layer structure 22 is subjected to total internal reflection at the interface toward the TIR layer 44, in particular that proportion of the generated light which impinges on the interface with the TIR layer 44 at an angle of incidence that is greater than the critical angle of total internal reflection. The angle of incidence and the critical angle are determined with respect to a surface normal, that is to say a perpendicular, to the interface with the TIR layer 44. The critical angle of total internal reflection is dependent on the size of the jump in refractive index and decreases as the size of the jump in refractive index increases. That is to say that as the size of the jump in refractive index increases, the critical angle of total internal reflection decreases and an increasing proportion of the light has an angle of incidence that is greater than the critical angle, and a correspondingly increasing proportion of the generated light is subjected to total internal reflection at the interface.

With regard to its construction and/or material, the current supply layer 46 can be formed in accordance with a configuration of the first electrode 20 explained in association with the conventional optoelectronic component 1. By way of example, the current supply layer 46 may include or be formed from silver.

The current conducting elements 48 include an electrically conductive material. By way of example, the current conducting elements 48 can be formed by an electrically conductive adhesion medium, for example by electrically conductive paste, for example by silver conductive adhesive. As an alternative thereto, the current conducting elements 48 can be formed by a hard material, for example by soldering tin or copper. The current conducting elements 48 are embedded into the TIR layer 44 and are enclosed by the material of the TIR layer 44 in a horizontal direction in FIG. 4. As an alternative to the two current conducting elements 48, just one current conducting element 48 or else more than two, for example three, four or more, current conducting elements 48 can be arranged.

FIG. 9 shows a flow diagram of one embodiment of a method for producing an optoelectronic component, for example the optoelectronic component 10 explained above.

A step S40 involves providing a carrier, for example the carrier 12 explained above. Providing the carrier 12 may include for example forming the carrier 12, for example from a transparent substrate, for example a glass substrate or a film or a nontransparent substrate, for example a metal film. Furthermore, step S2 can involve, if appropriate, forming one or a plurality of barrier layers, coupling-out layers, for example scattering layers and/or other intermediate layers on the carrier 12.

A step S42 involves forming a current supply layer. By way of example, the current supply layer 46 is formed above the carrier 12. The current supply layer 46 can be formed for example in accordance with a configuration of the conventional first electrode 20.

A step S44 involves forming current conducting elements, for example the current conducting elements 48 explained above.

A step S46 involves forming a TIR layer. By way of example, the TIR layer 44 is formed above the current supply layer 46. The material of the TIR layer 44 can for example be deposited on the current supply layer 46 or be printed onto the latter. Furthermore, the material of the TIR layer 44 can be foamed, for example by means of air or nitrogen, before being applied or after being applied to the current supply layer 46. As an alternative thereto, the TIR layer 44 can be formed by creating a cavity, in particular a free volume above the current supply layer 46.

The order in which steps S44 and S46 are processed can vary depending on how the current conducting elements are formed. If, for example, firstly step S44 and then step S46 are performed, wherein firstly the current conducting elements 48 are formed and then the TIR layer 44 is formed, the current conducting elements 48 can be formed, for example, by soldering points being applied to the current distributing layer 42, by an electrically conductive adhesion medium being applied, for example at points, to the current distributing layer 42, or by solid small electrically conductive elements, for example copper points or cylinders, being applied to the current distributing layer 42. Afterward, the TIR layer 44 can be formed, specifically around the current conducting elements 48. If the TIR layer 44 is formed by a cavity or a free volume, for example firstly the current conducting elements 48 can be formed as spacers and then the current supply layer 46 can be applied to the current conducting elements 48 in such a way that the cavity remains between the current supply layer 46 and the current distributing layer 42.

If, for example, firstly step S46 and then step S44 are performed, wherein firstly the TIR layer 44 is formed and then the current conducting elements 48 are formed, for example holes can be formed in the TIR layer 42 and the material of the current conducting elements 48 can be filled or introduced into the TIR layer 44.

As an alternative thereto, steps S44 and S46 can be performed simultaneously and the TIR layer 44 and the current conducting elements 48 can be formed simultaneously and/or in one work step, for example by means of a printing method.

A step S48 involves forming a current distributing layer. By way of example, the current distributing layer 42 explained above is formed. The current distributing layer 42 can be formed for example by electrically conductive elements, for example the electrically conductive nanostructures, being dissolved in a suspension and the suspension being applied to the TIR layer 44. The carrier liquid of the suspension can then be partly or completely removed, for example by means of drying or evaporation. As an alternative thereto, the carrier liquid used can be a drying or curing material that cures after being applied to the TIR layer 44.

A step S50 can involve forming an organic functional layer structure 22, for example the organic functional layer structure 22 explained above. The organic functional layer structure 22 can be formed for example above the current distributing layer 42, for example directly on the current distributing layer 42. By way of example, the organic functional layer structure 22 can be deposited layer by layer or printed layer by layer.

A step S52 involves forming a light-transmissive electrode. By way of example, the second electrode 23 is formed in a light-transmissive fashion above the organic functional layer structure 12. The second electrode 23 can for example be deposited above the carrier 12 or be printed onto the latter.

Optionally, by way of example, the encapsulation layer 24, the adhesion medium layer 36 and/or the covering body 38 can also be arranged and/or formed above the second electrode 23.

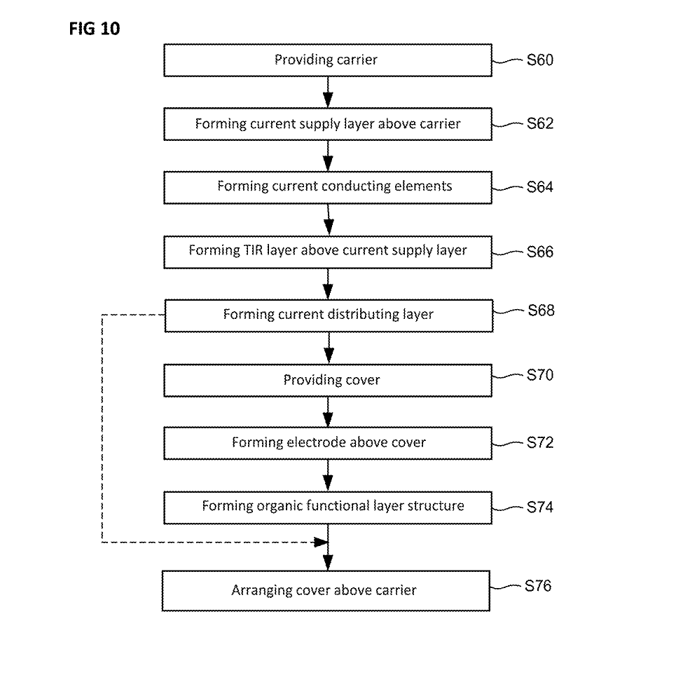

FIG. 10 shows a flow diagram of one embodiment of an alternative method for producing an optoelectronic component, for example the optoelectronic component 10 explained above.

Steps S60 to S66 can be processed for example analogously to steps S40 to S46 of the method explained above.

Forming the TIR layer 44 and the current conducting elements 48 can be carried out for example analogously to forming the current conducting elements 48 and the TIR layer 44 in accordance with steps S44 and S46. In particular, the order of the processing of steps S64 and S66 can be dependent on the type of current conducting elements 48 and/or the TIR layer 44.

A step S68 involves forming a current distributing layer. By way of example, the current distributing layer 42 explained above is formed. The current distributing layer 42 can be formed for example in accordance with step S48, specifically above the TIR layer 44.

As an alternative thereto, step S68 can also be performed after a step S74. In particular, the current distributing layer 42 can also be formed above the organic functional layer structure 22, which, as explained below, is formed above a cover.

A step S70 can involve providing the cover. By way of example, the cover may include the covering body 38, the adhesion medium layer 36 and/or the encapsulation layer 44.

A step S72 involves forming a light-transmissive electrode. By way of example, the second electrode 23 explained above is formed above the cover, for example directly on the cover. By way of example, the second electrode 23 can be deposited on the cover. The second electrode 23 can be formed for example in accordance with a configuration of the conventional second conventional electrode 23.

A step S74 involves forming an organic functional layer structure. By way of example, the organic functional layer structure 22 explained above is formed above the second electrode 23. Forming the organic functional layer structure 22 in step S74 can be carried out substantially analogously to forming the organic functional layer structure 22 above the TIR layer 44 in step S50.

Optionally, step S68 can then be carried out and the current distributing layer 42 can be formed above the organic functional layer structure 22.

In a step S76, the cover with the second electrode 23 and the organic functional layer structure 22 is arranged above the carrier 12, such that the current conducting elements 48, the current supply layer 46 and the current distributing layer 42 are electrically coupled to one another. In particular, the cover is arranged such that the covering body 38 faces away from the carrier 12.

The invention is not restricted to the embodiments indicated. By way of example, the optoelectronic component 10 may include a plurality of organic functional layer structure units which generate light of different colors, for example. Furthermore, the optoelectronic component 10, in terms of the external shape, can deviate from the external shape of the conventional optoelectronic component 1 as shown in FIG. 1. By way of example, the covering body 38 can extend toward an outer edge of the carrier 12 and the contact regions 32, 34 can be exposed in corresponding cutouts of the covering body 38. Furthermore, the methods explained with reference to FIGS. 6, 7, 9, 10 may include fewer or more steps, for example for producing coupling-out layers (not shown) or the like.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component, comprising:
a light-transmissive carrier,
a light-transmissive electrode above the carrier,
an organic functional layer structure, which has a first refractive index, above the first electrode,
a light-transmissive current distributing layer above the organic functional layer structure,
a light-transmissive TIR layer, which has a second refractive index, which is less than the first refractive index, above the current distributing layer,
a specularly reflective current supply layer above the TIR layer, and
at least one current conducting element which extends through the TIR layer and electrically couples the current supply layer and the current distributing layer to one another.

2. An optoelectronic component, comprising:
a carrier,
a specularly reflective current supply layer above the carrier,
a light-transmissive TIR layer above the current supply layer,
a light-transmissive current distributing layer above the TIR layer,
at least one current conducting element which extends through the TIR layer and electrically couples the current supply layer and the current distributing layer to one another,
an organic functional layer structure, which has a first refractive index, above the current distributing layer, and
a light-transmissive electrode above the organic functional layer structure,
wherein the light-transmissive TIR layer has a second refractive index,
which is less than the first refractive index.

3. The optoelectronic component as claimed in claim 1, wherein the second refractive index is in a range of 1 to 1.48.

4. The optoelectronic component as claimed in claim 1, wherein the TIR layer comprises plastic.

5. The optoelectronic component as claimed in claim 4, wherein the TIR layer comprises a foamed material.

6. The optoelectronic component as claimed in claim 4, wherein the TIR layer comprises epoxy.

7. The optoelectronic component as claimed in claim 1, wherein the TIR layer (44) comprises nanostructures, or wherein the TIR layer (44) comprises microstructures.

8. The optoelectronic component as claimed in claim 1, wherein the TIR layer is formed by a cavity.

9. The optoelectronic component as claimed in claim 8, wherein the current conducting element is formed as a spacer between the current distributing layer and the current supply layer.

10. The optoelectronic component as claimed in claim 1, wherein the electrode comprises nanowires.

11. The optoelectronic component as claimed in claim 1, wherein the current supply layer comprises silver.

12. The optoelectronic component as claimed in claim 1, wherein the current conducting element is formed by electrically conductive adhesion medium.

13. A method for producing an optoelectronic component, the method comprising:
providing a light-transmissive carrier,
forming a light-transmissive electrode above the carrier,
forming an organic functional layer structure, which has a first refractive index, above the first electrode,
forming a light-transmissive current distributing layer above the organic functional layer structure,
forming a light-transmissive TIR layer, which has a second refractive index, which is less than the first refractive index, above the current distributing layer and forming at least one current conducting element such that it extends through the TIR layer for the purpose of electrically coupling the current distributing layer to a specularly reflective current supply layer, and
forming the specularly reflective current supply layer above the TIR layer.

14.-16. (canceled)
